(19) United States
(12) Patent Application Publication
(10) Pub. No.: US 2026/0059835 A1
(43) Pub. Date: Feb. 26, 2026

(54) SILICON CARBIDE SEMICONDUCTOR CONTACT STRUCTURES

(71) Applicant: X-FAB Texas Inc., Lubbock, TX (US)

(72) Inventors: Yanwen Chen, Lubbock, TX (US); Yon Lee, Lubbock, TX (US); Tyler Tucker, Lubbock, TX (US); Jeff Smith, Shallowater, TX (US); Sara Hahmady, Lubbock, TX (US); Kris Whitaker, Lubbock, TX (US)

(21) Appl. No.: 19/189,790

(22) Filed: Apr. 25, 2025

Related U.S. Application Data
(63) Continuation-in-part of application No. 18/813,319, filed on Aug. 23, 2024.

(51) Int. Cl. H10D 64/23; H01L 23/532; H10D 30/01; H10D 30/66; H10D 62/60; H10D 62/832; H10D 64/62

(52) U.S. Cl. CPC H10D 64/2527; H01L 23/53214; H01L 23/53228; H10D 30/0295; H10D 30/0297; H10D 30/665; H10D 30/668; H10D 62/60; H10D 62/8325; H10D 64/62

(57) ABSTRACT

A silicon carbide device including a trench contact structure configured to connect to a part of a transistor. The trench contact structure includes a trench having sidewalls, a silicide layer located in the trench and covering the sidewalls, and a metal contact element located in the trench and connected to the part of the transistor via the silicide layer.

This application is a continuation-in-part of U.S. patent application Ser. No. 18/813,319 filed on Aug. 23, 2024, the entire contents of which are hereby incorporated by reference.

### TECHNICAL FIELD

The invention concerns silicon carbide (SiC) contact structures and methods of forming such.

### BACKGROUND

Silicon carbide technology is seeing increasing interest as an alternative to conventional silicon technology for specific application areas. However, due to the unique properties of this material, conventional semiconductor processing developed for silicon technology may not be directly usable. Therefore, new methods and processes for forming SiC devices are required.

Currently in SiC processing the contacts and “vias” to the top “power” metal are formed by depositing and reflowing an interlayer dielectric (ILD), depositing Nickel and forming NiSi contacts, and then finally depositing the power metal. A similar process is described in U.S. Patent Application Publication No. 2020/0365708, which uses a reflowed dielectric. However, these processes can put limitations on the dimensions of SiC devices, which, as the technology shrinks, will become a problem in future.

### SUMMARY

Aspects of the present disclosure provide a SiC device and methods of forming a contact structure for such a SiC device, as set out in the appended claims.

Specific embodiments will now be described with reference to the accompanying drawings.

### BRIEF DESCRIPTION OF DRAWINGS

FIG. 1 shows a schematic cross section of a part of a SiC wafer;

FIGS. 2A, 2B, 2C, 2D, 2E, 2F and 2G show subsequent schematic cross sections of a part of a SiC wafer during contact formation;

FIG. 3 shows a schematic cross section of a contact structure of a SiC device;

FIG. 4 shows a flow diagram illustrating the steps of a method of making a contact structure for a SiC device;

FIGS. 5A, 5B, 5C, 5D, 5E, 5F, 5G, 5H and 5I show at least some of the steps of a method of forming a semiconductor structure;

FIGS. 6A, 6B, 6C, 6D, 6E, 6F and 6G show at least some of the steps of an alternative method of forming a semiconductor structure; and

FIGS. 7A, 7B, 7C, 7D, 7E, 7F and 7G show at least some of the steps of a method of forming a semiconductor structure with a recessed gate structure.

### DETAILED DESCRIPTION

Power semiconductor devices are used to carry large currents and support high voltages. A wide variety of power semiconductor devices are known in the art including, for example, power Metal Oxide Semiconductor Field Effect Transistors (“MOSFETs”), Insulated Gate Bipolar Transistors (“IGBTs”) and various other devices. These power semiconductor devices can be fabricated from wide bandgap semiconductor materials such as silicon carbide (SiC) or gallium nitride (GaN) based materials (herein, the term “wide bandgap semiconductor” encompasses any semiconductor having a bandgap of at least 1.4 eV). Power semiconductor devices are designed to block (in the forward or reverse blocking state) or pass (in the forward operating state) large voltages and/or currents. For example, in the blocking state, a power semiconductor device may be designed to sustain hundreds or thousands of volts of electric potential.

Power semiconductor devices can have a lateral structure or a vertical structure. In a device having a lateral structure, the terminals of the device (e.g., the drain, gate and source terminals for a power MOSFET) are on the same major surface (i.e., upper or lower) of a semiconductor layer structure. In contrast, in a device having a vertical structure, at least one terminal is provided on each major surface of the semiconductor layer structure (e.g., in a vertical MOSFET, the source and gate may be on the upper surface of the semiconductor layer structure and the drain may be on the bottom surface of the semiconductor layer structure). Vertical structures are typically used in very high power applications, as the vertical structure allows for a thick semiconductor drift layer that can support high current densities and block high voltages. Herein, the term “semiconductor layer structure” refers to a structure that includes one or more semiconductor layers such as semiconductor substrates and/or semiconductor epitaxial layers.

A conventional vertical silicon carbide power MOSFET includes an epitaxial layer structure that is formed on a silicon carbide substrate, such as a silicon carbide wafer. The epitaxial layer structure (which may comprise one or more separate layers) functions as a drift region of the power semiconductor device. The MOSFET may have an active region that is formed on and/or in the drift region in which one or more semiconductor devices are formed, as well as a termination region that may surround the active region. The active region acts as a main junction for blocking voltage in the reverse bias direction and providing current flow in the forward bias direction. The power MOSFET typically has a unit cell structure, meaning that the active region includes a large number of individual “unit cell” MOSFETs that are electrically connected in parallel to function as a single power MOSFET. In high power applications, such a device may include thousands or tens of thousands of unit cells.

To at least partly overcome the existing problems of SiC contact formation for a source contact of a SiC transistor, it is proposed to form a gate aligned silicide on the source region of a SiC transistor before providing an ILD and forming the metal via (also referred to as “metal plug”). To shrink cell pitches, reduce reliance of lithography processes, and improve device performance of SiC devices, the silicide needs to be formed before the ILD is deposited.

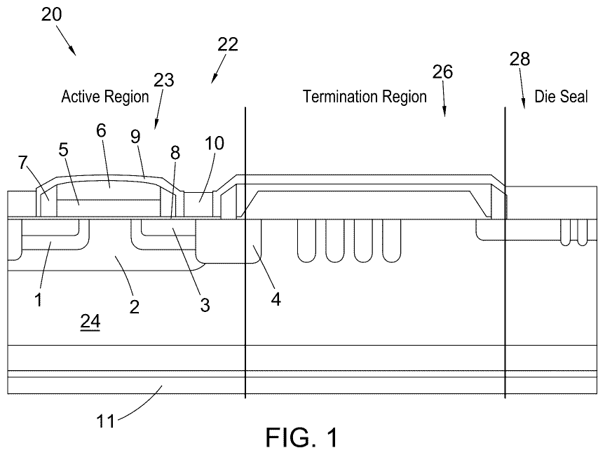

FIG. 1 shows a schematic cross section of a part of SiC wafer/die 20 comprising a semiconductor structure 22 comprising a vertical transistor. The semiconductor structure 22 comprises PWell region 1, a JFET region 2, an NPlus (n+) region 3 (also referred to as the source region), a PPlus (p+) region 4, a gate structure 23 comprising a conductive gate layer 5 (typically doped polysilicon) on the gate oxide (GOX), and an insulating gate layer 6 as well as oxide gate spacers 7. On the NPlus region 3 there is located an ohmic contact 8 (e.g. a NiSi silicide layer), connected to a metal via 10 through the inter layer dielectric (ILD) layer 9. The metal via 10 (typically tungsten) provides the electrical connection between the source region 3 and the power metal (not shown). On the other side of the substrate 24, a drain contact 11 is located. In use, when the transistor is on, electrons flow from the source region 3 through the substrate 24 and to the drain contact 11.

FIG. 1 further shows a termination region 26 of the wafer 20 and a die seal 28 of the wafer 20, located at the edge of the wafer 20. Typically, a plurality of SiC devices (such as the illustrated transistor) may be located adjacent to each other between termination regions 26. The termination region 26 may improve the electric fields at the edges of SiC devices, for example by including one or more doped rings that can help spread an electric field in the substrate 24.

To form a gate aligned silicide, multiple layers are provided before beginning the ILD process. To form silicide contacts before ILD deposition a layer of TEOS can be added to the gate poly stack. This oxide layer ensures that nickel will not contact poly during the rapid thermal process (RTP) step of silicidation. The Gate poly stack can be patterned and then go through an oxide etch and followed by the standard poly etch to form the so called gate runners.

To protect the gate poly sidewalls from nickel, another high uniformity TEOS layer can be deposited. This TEOS layer can vary in thickness but may be at least 1 kÅ thick to provide sufficient protection. The wafer then undergoes a sidewall oxide etch to clear the SiC surface for Nickel deposition and form oxide gate spacers of the gate structure.

Nickel can then be deposited and silicided to form a low resistance layer or ohmic contact on the semiconductor layer (over the source region).

Whilst gate aligned contacts are not new to silicon technology as such, it has not been previously considered for SiC processes where well and contact formation is not patterned by the gate. Until now there has not been a need to shrink contacts smaller than 1.0 μm on SiC, which has allowed the conventional SiC contact formation.

To successfully shrink vias and the cell pitch, it may be desired to use tungsten (W) deposition and etch back like that, which can help to provide vias smaller than 1.0 μm, while mitigating potential gate leakage. The W plug process can allow for better control of the ILD, better metal fill, and smaller cell pitches.

The tungsten plug process starts after the silicide formation with depositing the ILD (e.g. silicon oxide formed by TEOS and borophosphorous TEOS (BPTEOS), followed by densification). Then the openings in the ILD for the source vias are patterned and etched. In conventional technology, after a source via etch, there is another process to reflow the ILD that gives it a sloped profile, but for the proposed tungsten plug process this is not used. Instead, tungsten and any barrier layers are deposited and etched back. This can provide a planar surface for the power metal to be deposited on. This process also gives the ability to make contact to both gate and source with a single etch as the NiSi contacts have already been formed.

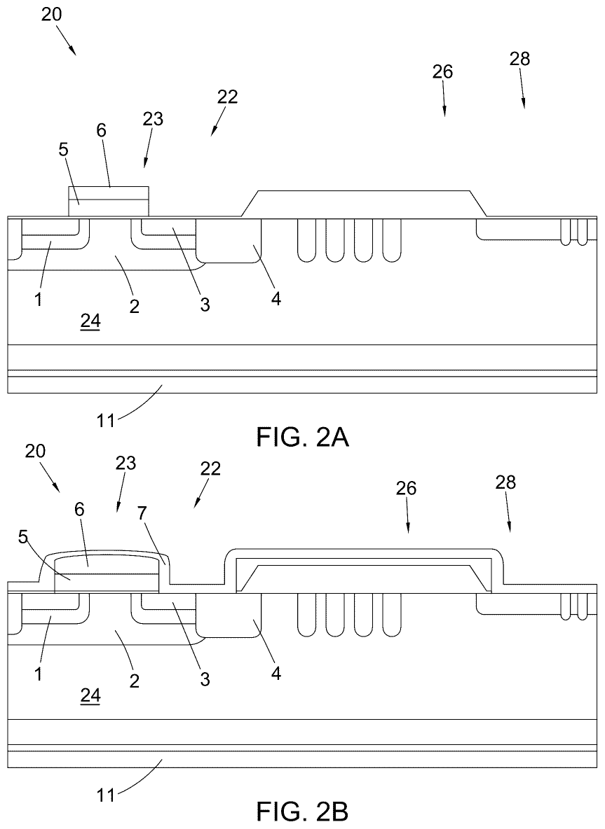

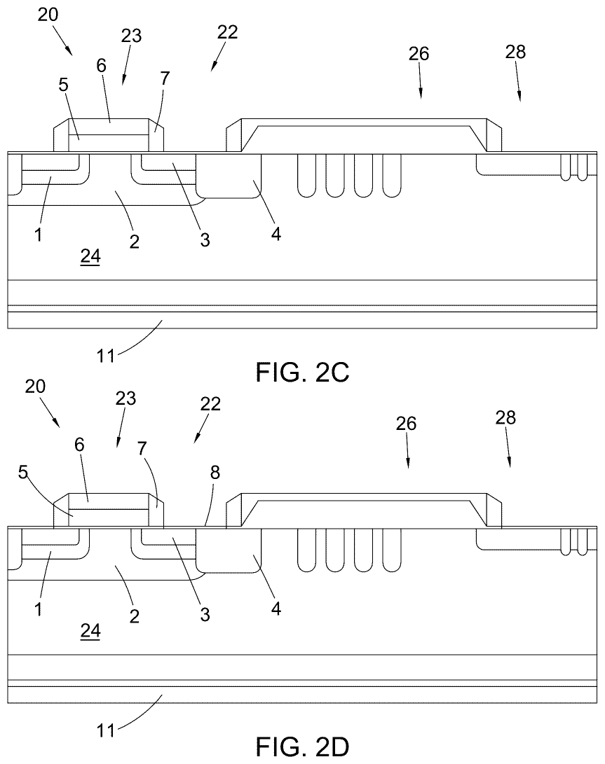

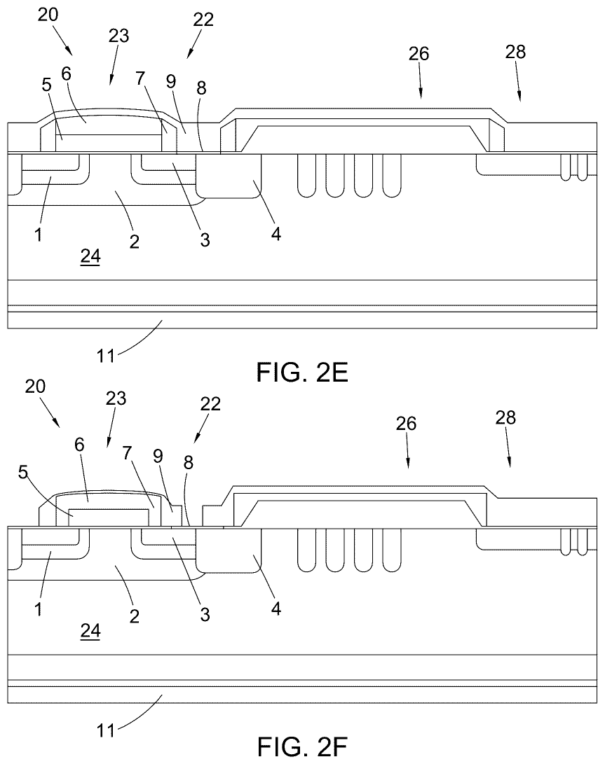

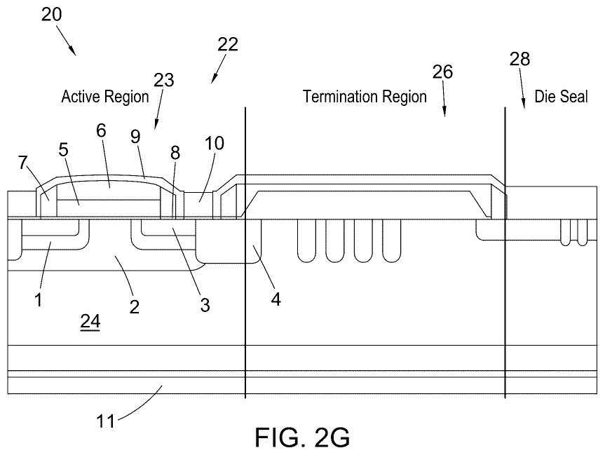

FIGS. 2A to 2G show sequential cross sections of a semiconductor structure 22 in the contact formation processes in order to provide the contact structure described in relation to FIG. 1 above. To aid understanding, the same reference numerals have been used for equivalent features in different figures.

In FIG. 2A, the gate structure 23 has been patterned and etched to form a gate runner comprising the gate oxide, the conductive gate layer 5 (e.g. poly) and the insulating gate layer 6 (e.g. silicon oxide).

In FIG. 2B, a dielectric layer for forming gate spacers 7 is blanket deposited over the gate structure and over the NPlus source region 3.

In FIG. 2C, the dielectric layer is patterned (comprising an etch step) to form gate spacers 7 and to expose the underlying NPlus source region 3.

In FIG. 2D, the ohmic contact 8 is formed on the NPlus region 3. The ohmic contact 8 is aligned to the gate structure 23, while the gate is protected by the gate spacers 7. The ohmic contact 8 may be formed by depositing Ni, thermally reacting the Ni with the underlying SiC material to form a silicide, and then removing any excess (unreacted) Ni.

In FIG. 2E, an ILD 9 is blanket deposited over the gate structure 23 and over the NPlus source region 3 (on top of the ohmic contact 8). The ILD 9 may comprise a combination of silicon oxide and a reflowable BPTEOS.

In FIG. 2F, the ILD 9 is patterned and etched to form openings over the NPlus source region 3 down to the ohmic contact 8.

In FIG. 2G, metal vias 10 are formed in the opening of the ILD 9 to connect the ohmic contacts 8 and thereby the source region 3. Forming the metal vias 10 may comprise depositing one or more barrier layers (not shown), depositing tungsten and then removing the tungsten on top of the ILD 9 by etching. The etchback to remove the excess tungsten typically stops on the barrier layers.

In general, embodiments described herein provide a method of forming a contact structure for a silicon carbide semiconductor device, the method comprising the following steps in the following order:
forming a gate structure for a transistor comprising a source region in a semiconductor layer;
forming a silicide layer on the source region, wherein the silicide layer is self-aligned with the gate structure;
providing a dielectric layer over the silicide layer;
patterning the dielectric layer to form an opening to the silicide layer; and
providing a metal in the opening to form an electric contact to the source region.

The step of forming the gate structure may comprise:
forming a gate oxide layer on the semiconductor layer;
depositing a polysilicon layer on the gate oxide layer;
doping the polysilicon layer with a dopant; and
patterning the polysilicon layer and the gate oxide.

A layer of tungsten silicide (WSi) may also be deposited on the polysilicon layer followed by a silicon oxide.

Before patterning the polysilicon layer, the method may comprise depositing a Silicon oxide layer being tetraethoxysilane (TEOS) layer for protecting the gate structure.

Providing the dielectric layer may comprise blanket depositing a layer of silicon oxide over said source region and over said gate structure.

Forming a gate structure may further comprise, forming gate spacers, which may comprise depositing an oxide layer and etching the oxide layer to reveal the source region.

Forming the silicide layer may comprise:
depositing nickel on the source region;
heating nickel to cause silicide to form on the source region;
removing unreacted nickel; and
annealing the silicide.

Patterning the dielectric layer typically comprises photolithography to form the opening with substantially vertical side walls. The opening may have a width that is less than or equal to 1.0 μm. This is substantially smaller than what existing technology for SiC can produce with sufficiently high quality. In one case, the metal is tungsten, which can provide a better fill than copper.

The semiconductor layer can be formed on a first side of a semiconductor substrate and a drain region of the transistor can be located on a second and opposite side of the semiconductor substrate (a vertical transistor).

Embodiments described herein can further provide a silicon carbide device comprising a semiconductor structure formed as described above.

Embodiments may provide a silicon carbide device comprising:
gate structure for a transistor;
a semiconductor layer comprising a source region of a source of the transistor;
a silicide layer on the source region, wherein the silicide layer is self-aligned with the gate structure;
a dielectric layer over the silicide layer; and
a metal via through the dielectric layer and connected to the source region.

The metal via in one case comprises tungsten, and the via is in one case no wider than 1 μm.

Another way to provide an improved contact structure for the contact of a SiC device is to provide a shallow trench into the semiconductor layer and then form a silicide layer in the trench so that it covers the sidewalls of the trench. This arrangement can provide an increased interface between the metal contact element and the contact region via the silicide. The contact may be the source or drain contact of a transistor.

The self-aligned silicidation and W-plug vias can be combined with the recessed contact structure. The recessed contact can further improve both device performance and reliability. The contact to the source/drain region is via the shallow trench sidewalls, which can provide further cell pitch shrink. The recessed contact structure can also reduce the current path in p-type well, thereby suppressing parasitic bipolar turn-on during surge current scenario (thus increasing unclamped inductive switching (UIS) or dV/dt ruggedness). The recessed contact structure can also more effectively limit the saturation current in short-circuit events, increasing device short-circuit withstand time (SCWT).

This recessed source contact structure may comprise the following features:
1) a shallow trench in SiC material (formed by SiC etch), with a typical width smaller than 1.0 um, a depth between 0 to 1.0 um, and a trench sidewall angle (between trench bottom and trench sidewall) range from 90 to 180 degree.
2) For a source contact, the contact recess (or trench depth) is deeper than source region (N+ region), in such way that the contact trench bottom contacts a top of a P-type region (P+ region) and the contact trench sidewalls cover the whole N+ region.
3) A Nickel or Titanium silicide layer formed on all SiC surfaces of the recessed contact structure (on the trench bottom and sidewalls) to achieve Ohmic contact.
4) W-plug via (width smaller than 1.0 um) connecting the silicide layer with a top metal layer (the Power Metal layer), and which is insulated from the gate poly by an interlayer dielectric (ILD).

This recessed contact structure can be implemented in both planar gate and trench gate SiC MOSFETs, through several manufacturing approaches (see attached sheets).

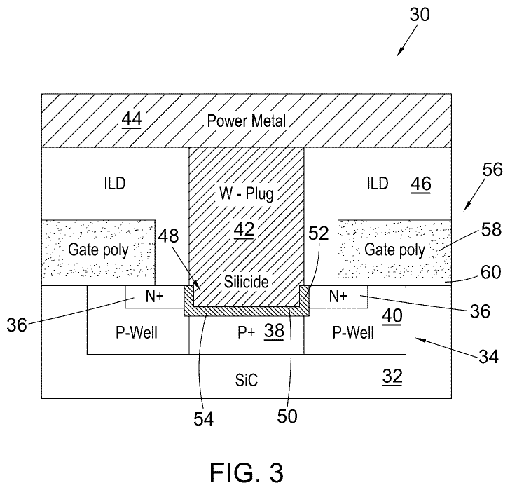

FIG. 3 shows a schematic cross section of a contact structure 30 of a SiC device (e.g. a vertical transistor). The contact structure 30 comprises a semiconductor layer 32 (e.g. one or more layers of epitaxial SiC) comprising a contact region 34 comprising a source region (N+ regions) 36 and P+ region 38 in a P-well 40. The N+ regions 36 are shorted to the P+ region 38 for improved reliability.

The contact structure comprises a tungsten contact element 42 (also referred to as a tungsten plug 42) which extends from the power metal layer 44, through the dielectric layer 46 (also referred to as “interlayer dielectric”), to the source region 36. A trench 48 is formed in the semiconductor layer 32. The trench 48 has a bottom 50 that interfaces the P+ region 38 and sidewalls 52 that interface the N+ regions 36. A silicide layer 54 covers the trench 48 in the semiconductor layer 32. The tungsten plug 42 contacts the contact region 34 via the silicide layer 54. The trench 48 can increase the size of the interface between the tungsten plug 42 and the semiconductor layer 32. The combination of the trench 48 and the tungsten plug 42 can allow for an improved connection, while also allowing for a planar power metal layer 44.

The contact structure 30 further comprises a gate structure 56 comprising a patterned gate poly layer 58 on gate oxide 60. FIG. 3 may illustrate a part of a vertical transistor, which also comprises a drain (not shown), which would then be located in or below the semiconductor layer 32 on the opposite side to the contact region 34.

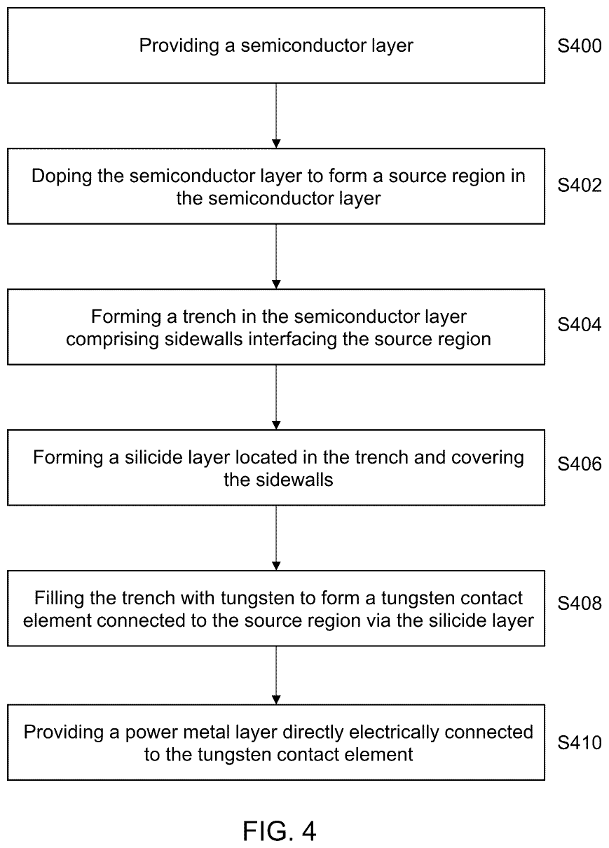

FIG. 4 shows a flow diagram illustrating the steps of a method of making a contact structure for a silicon carbide device. The method comprises providing a semiconductor layer (S400) and doping the semiconductor layer to form a source region in the semiconductor layer (S402). The method further comprises forming a trench in the semiconductor layer comprising sidewalls interfacing the source region (S404), forming a silicide layer located in the trench and covering the sidewalls (S406) and filling the trench with tungsten to form a tungsten contact element connected to the source region via the silicide layer (S408). Then the method comprises providing a power metal layer directly electrically connected to the tungsten contact element (S410).

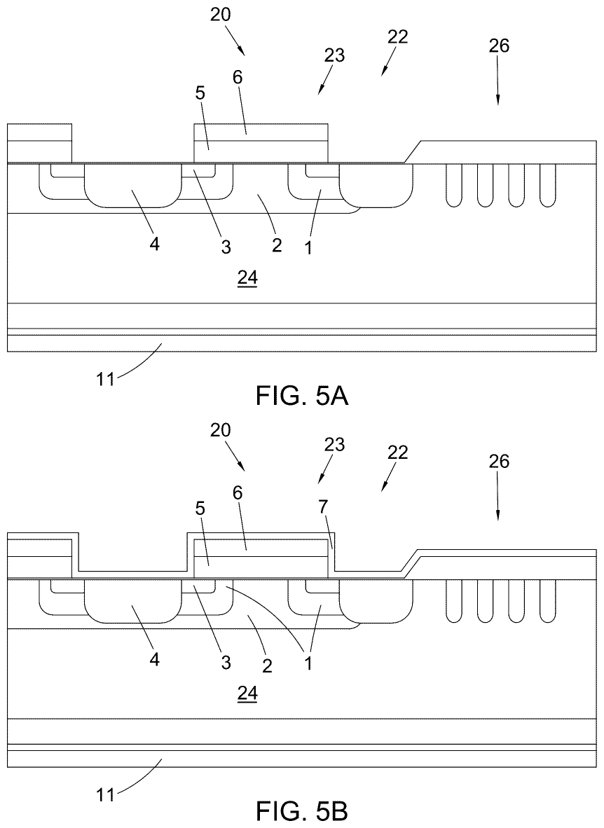

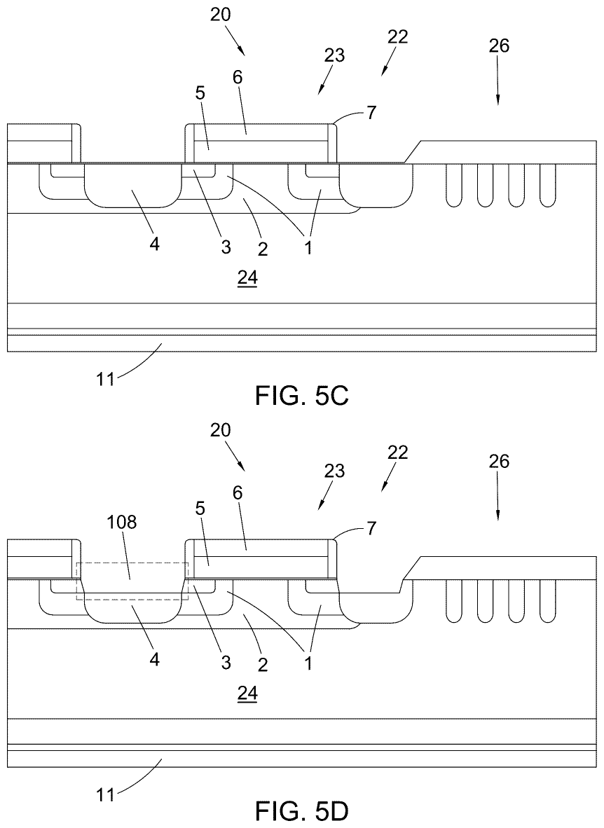

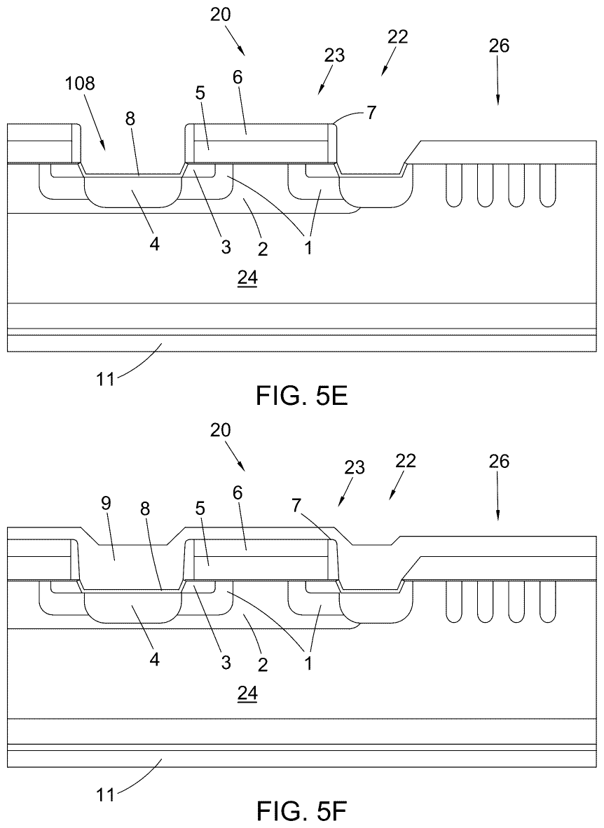

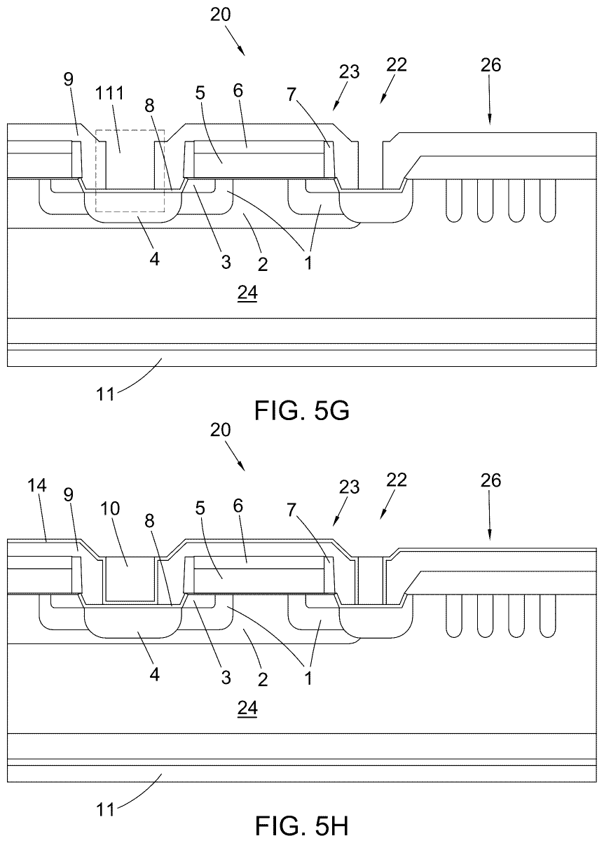

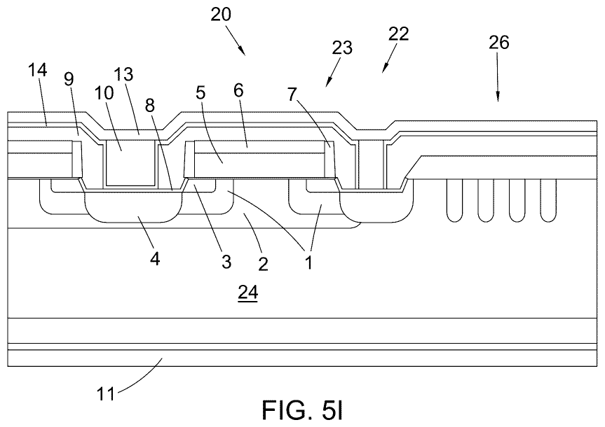

FIGS. 5A to 5I illustrate at least some of the steps of a method of forming a semiconductor structure 22. In particular, the figures illustrate subsequent cross sections of a part of a SiC wafer 20 in the method of forming a source contact structure of a vertical transistor. The transistor comprises a contact region comprising a source region 3 being an N+ region. The transistor further comprises and a drain region 11 on the opposite side of the wafer. The N+ region 3 is formed in a P-well 1 and is shorted to a P+ region 4. The doped regions 1, 3 and 4 are formed in the (active) semiconductor layer 2 of the semiconductor structure 22. In this embodiment, the semiconductor layer 2 can also be referred to as the JFET region 2. The semiconductor layer 2 may be a lightly doped epitaxial semiconductor layer, e.g. an epitaxial silicon carbide layer grown on a silicon carbide substrate 24. The gate poly layer 5 overlaps a part of the P-well 1 and the N+ region 3 and the junction between them.

In FIG. 5A, the gate structure 23 has been patterned and etched to form a gate runner comprising the gate oxide, the conductive gate layer 5 (e.g. poly) and the insulating gate layer 6 (e.g. silicon oxide). In particular, to provide the semiconductor structure 22 at the stage illustrated in FIG. 5A, the method may comprise the following preceding steps in the following order:
1. Forming a gate oxide layer (e.g. silicon oxide);
2. Depositing a gate poly layer 5 on the gate oxide layer;
3. Doping the gate poly layer 5;
4. Optionally, depositing WSi on the gate poly layer 5 for low gate resistance;
5. Depositing a TEOS layer 6 for gate poly protection;
6. Patterning the gate structure 23:
6a: Etching the gate poly protection layer 6;
6b: Etching the gate poly layer 5.

Doping regions 1, 2, 3 and 4 are formed before the gate oxide layer in a front-end process step.

In FIG. 5B, a gate spacer oxide layer 7 (also referred to as dielectric layer 7) has been deposited over the semiconductor structure 22. The gate spacer oxide layer covers the gate structure 23, and exposed parts of doped regions 3 and 4.

In FIG. 5C, the gate spacer oxide layer 7 is patterned (comprising an etch step) to form gate spacers 7 and to expose the underlying source regions 3 and P+ region 4.

In FIG. 5D, a trench 108 is etched into the (active) semiconductor layer 2. The etch removes a part of the N+ regions 3 and the P+ region 4 and exposes sidewalls of the N+ regions 3. The contact trench etch is self-aligned to the gate structure 23, with the gate spacers 7 shielding the gate poly layer 5. Hence, no pattern step is needed for the trench etch, which can reduce the risk of any potential misalignment. The self-aligned process can also allow reduced cell pitch and help prevent gate-to-source leakage.

In certain embodiments, forming the trench 108 may advantageously use a new etching technique. Due to the inert nature of SiC, dry etching of SiC can be challenging. Existing masks and etch parameters for etching silicon are in general not applicable to SiC. The new etching technique comprises a plasma etch that provides 1) a high SiC-to-SiO2 etch selectivity (causing minimal oxide loss), 2) sloped contact trench sidewalls (causing an enlarged sidewall contact area), and 3) a smooth trench surface, which can reduce contact resistivity. The plasma etch may be based on sulphur hexafluoride (SF6) gas chemistry. The plasma etch may further comprise an optimal combination of chamber pressure and RF power.

In FIG. 5E, the ohmic contact 8 is formed in the trench 108. The ohmic contact is formed on the N+ region 3 (i.e. in direct contact with the source region) and on the P+ region 4 (providing a short between the two regions). The ohmic contact 8 is aligned to the gate structure 23, while the gate is protected by the gate spacers 7. The ohmic contact 8 may be formed by depositing Ni, thermally reacting the Ni with the underlying SiC material to form a silicide, and then removing any excess (unreacted) Ni. Alternatively, the ohmic contact may be formed by titanium.

In FIG. 5F, an interlayer dielectric (ILD) 9 is blanket deposited over the gate structure 23 and over the ohmic contact 8. The ILD 9 may comprise silicon oxide or a combination of silicon oxide and a reflowable BPTEOS.

In FIG. 5G, the ILD 9 is patterned and etched to form openings 111 down to the ohmic contact 8. The etch stops on the ohmic contact 8.

In FIG. 5H, a metal via 10 (also referred to as a “plug”) is formed in the opening 111 of the ILD 9 to contact the ohmic contacts 8. Forming the metal vias 10 may comprise depositing one or more barrier layers 14, depositing tungsten and then removing the tungsten on top of the ILD 9 by etching. The etchback to remove the excess tungsten typically stops on the barrier layers.

In FIG. 5I, a power metal layer 13 is deposited over the wafer 20. The power metal layer 13 may comprise copper or aluminium. The metal plug 10 provides an electrical contact between the power metal layer and the N+ region 3 (i.e. the source region) of the transistor. Due to the metal plug 10, the power metal 13 does not have to reach down into trench 108 or trench 111, which can prevent metal filling void and allow for a smaller footprint of the source contact. The power metal layer 13 is arranged substantially flat on top of the metal plug 10.

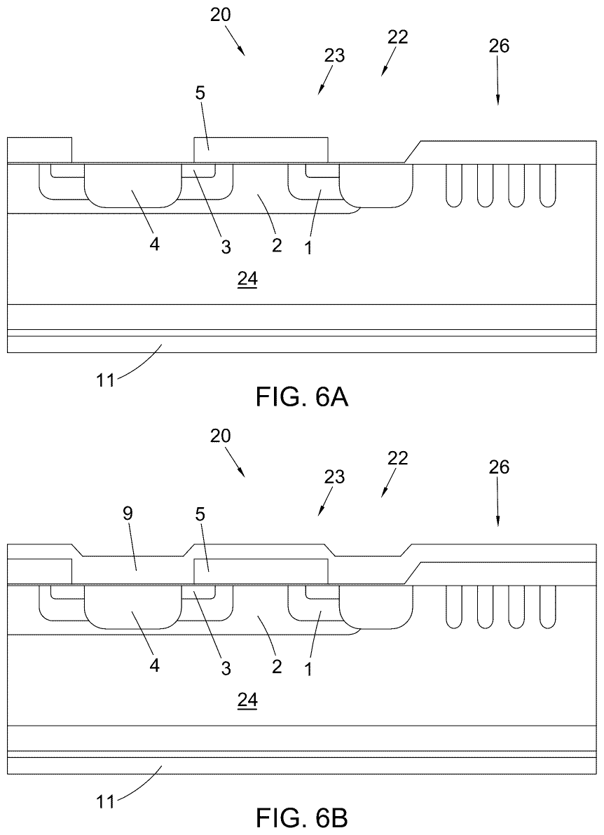

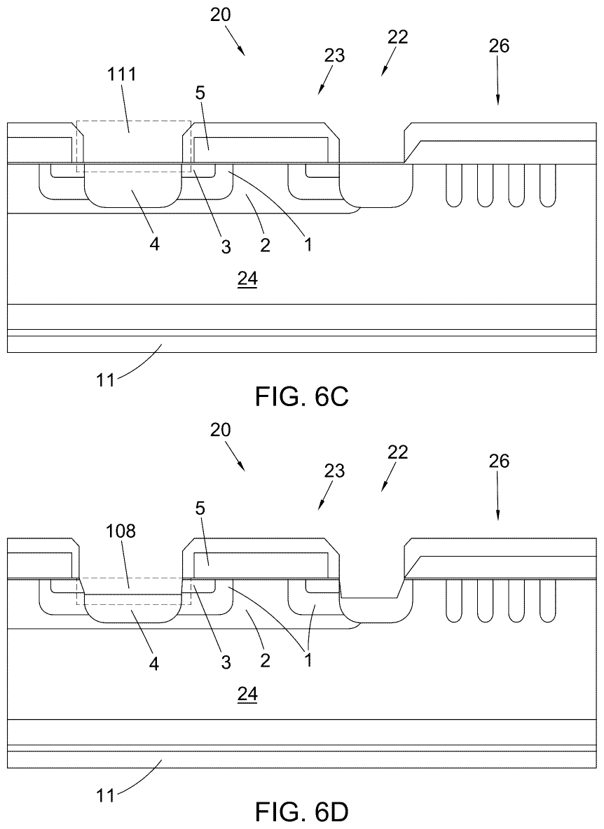

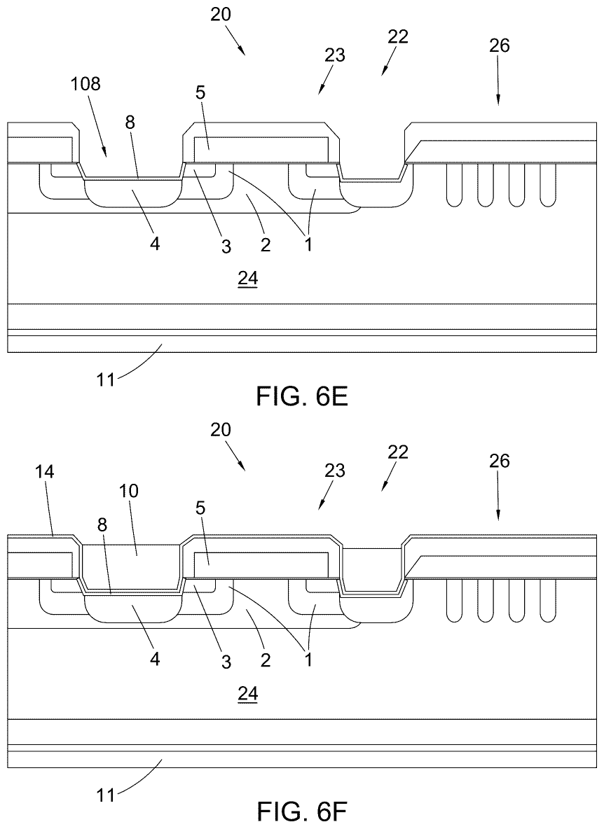

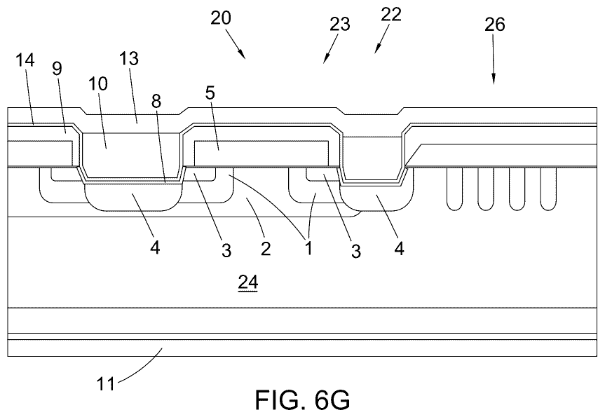

FIGS. 6A to 6G illustrate at least some of the steps of a method of forming a semiconductor structure 22. In particular, the figures illustrate subsequent cross sections of a part of a SiC wafer 20 in the method of forming a source contact structure of a vertical transistor. The transistor comprises a source region 3 being an N+ region, and a drain region 11 on the opposite side of the wafer. The N+ region 3 is formed in a P-well 1 and is shorted to a P+ region 4. The doped regions 1, 3 and 4 are formed in the (active) semiconductor layer 2 of the semiconductor structure 22. In this embodiment, the semiconductor layer 2 can also be referred to as the JFET region 2. The semiconductor layer 2 may be a lightly doped epitaxial semiconductor layer, e.g. an epitaxial silicon carbide layer grown on a silicon carbide substrate 24. The gate poly layer 5 overlaps a part of the P-well 1 and the N+ region 3 and the junction between them.

In FIG. 6A, the gate structure 23 has been patterned and etched to form a gate runner comprising the gate oxide and the conductive gate layer 5 (e.g. poly) a. In particular, to provide the semiconductor structure 22 at the stage illustrated in FIG. 6A, the method may comprise the following preceding steps in the following order:
1. Forming a gate oxide layer (e.g. silicon oxide);
2. Depositing a gate poly layer 5 on the gate oxide layer;
3. Doping the gate poly layer 5;
4. Optionally, depositing WSi on the gate poly layer 5 for low gate resistance;
5. Patterning the gate structure 23.

In FIG. 6B, an interlay dielectric (ILD) layer 9 has been deposited on the wafer 20. The ILD layer 9 covers the source region 3 and the gate structure 23. In this embodiment, the ILD layer 9 may be used as a protective insulating layer on the gate poly 5, instead of depositing a dedicated TEOS layer 6 as in FIG. 5A. The ILD 9 may comprise silicon oxide or a combination of silicon oxide and a reflowable BPTEOS.

In FIG. 6C, the ILD 9 is patterned and etched to form openings 111 down to the active silicon layer 2. The etch stops on the silicon.

In FIG. 6D, a trench 108 is etched into the (active) semiconductor layer 2. The etch removes a part of the N+ regions 3 and a part of the P+ region 4 and exposes sidewalls of the N+ regions 3. The contact trench etch is self-aligned to the ILD openings 111, with ILD 9 shielding the gate poly layer 5. Hence, no pattern step is needed for the trench etch, which can reduce the risk of any potential misalignment. The self-aligned trench etch process can also allow reduced cell pitch and help prevent gate-to-source leakage.

In certain embodiments, forming the trench 108 may advantageously use a new etching technique. Due to the inert nature of SiC, dry etching of SiC can be challenging. Existing masks and etch parameters for etching silicon are in general not applicable to SiC. The new etching technique comprises a plasma etch that provides 1) a high SiC-to-SiO2 etch selectivity (causing minimal oxide loss), 2) sloped contact trench sidewalls (causing an enlarged sidewall contact area), and 3) a smooth trench surface, which can reduce contact resistivity. The plasma etch may be based on sulphur hexafluoride (SF6) gas chemistry. The plasma etch may further comprise an optimal combination of chamber pressure and RF power.

In FIG. 6E, the ohmic contact 8 is formed in the trench 108. The ohmic contact is formed on the N+ region 3 (i.e. in direct contact with the source region) and on the P+ region 4 (providing a short between the two regions). The ohmic contact 8 is aligned to the gate structure 23, while the gate is protected by the ILD 9. The ohmic contact 8 may be formed by depositing Ni, thermally reacting the Ni with the underlying SiC material to form a silicide, and then removing any excess (unreacted) Ni. Alternatively, the ohmic contact may be formed by titanium.

In FIG. 6F, a metal via 10 (also referred to as a “plug”) is formed in the opening 111 of the ILD 9 to contact the ohmic contacts 8. Forming the metal vias 10 may comprise depositing one or more barrier layers 14, depositing tungsten and then removing the tungsten on top of the ILD 9 by etching. The etchback to remove the excess tungsten typically stops on the barrier layers.

In FIG. 6G, a power metal layer 13 is deposited over the wafer 20. The power metal layer 13 may comprise copper or aluminium. The metal plug 10 provides an electrical contact between the power metal layer and the N+ region 3 (i.e. the source region) of the transistor. Due to the metal plug 10, the power metal 13 does not have to reach down into trench 108 or trench 111, which can prevent metal filling void and allow for a smaller footprint of the source contact. The power metal layer 13 is arranged substantially flat on top of the metal plug 10.

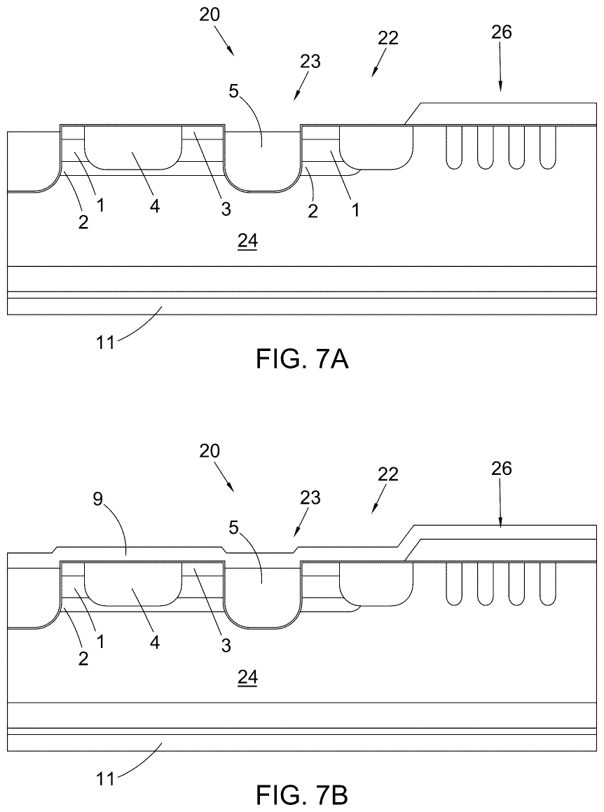

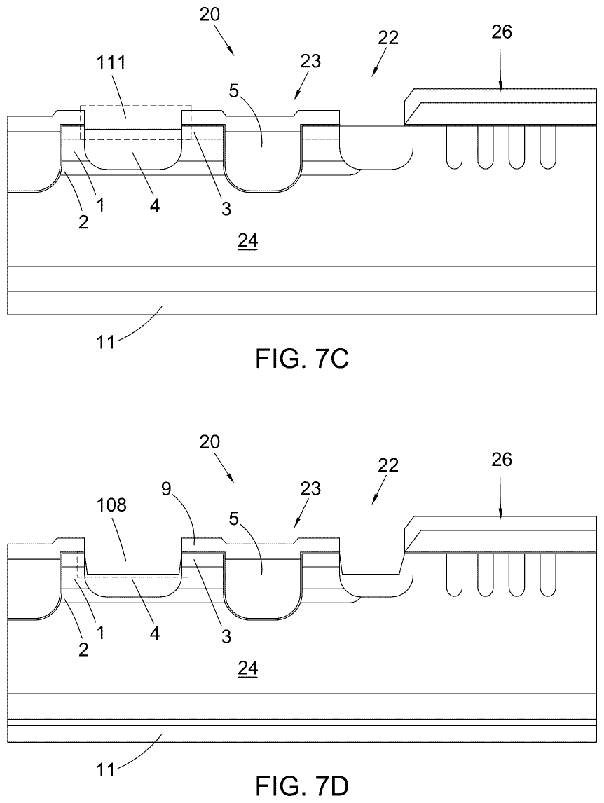

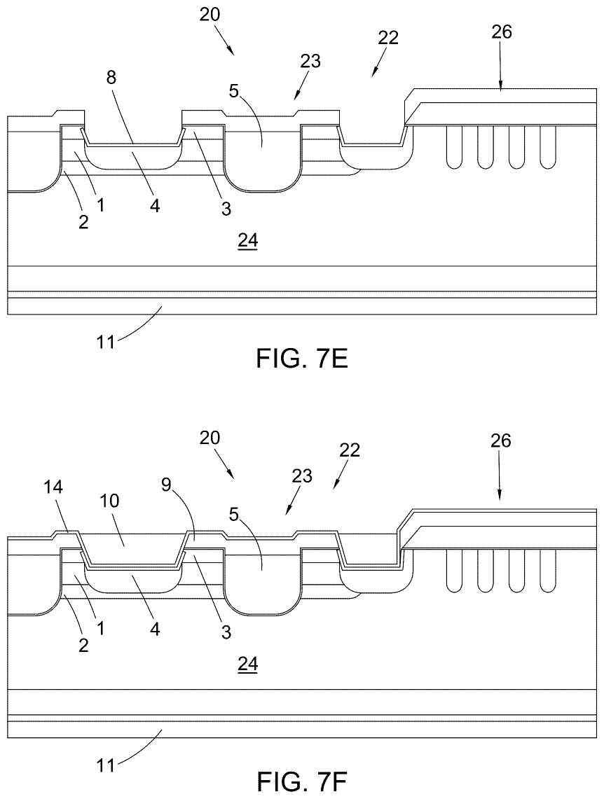

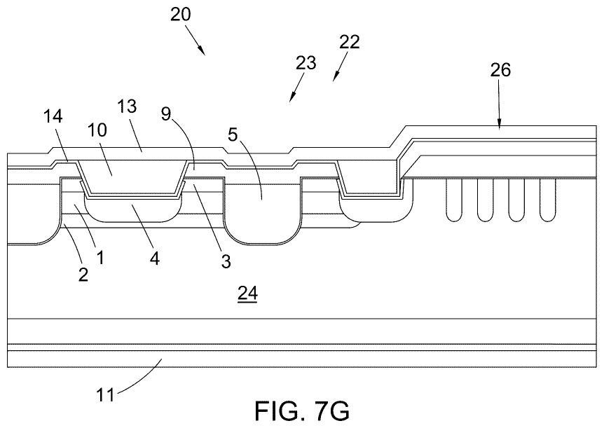

FIGS. 7A to 7G illustrate at least some of the steps of a method of forming a semiconductor structure 22. In particular, the figures illustrate subsequent cross sections of a part of a SiC wafer 20 in the method of forming a source contact structure of a vertical transistor with a recessed gate structure 23. The transistor comprises a source region 3 being an N+ region, and a drain region 11 on the opposite side of the wafer. The N+ region 3 is formed in a P-well 1 and is shorted to a P+ region 4. The doped regions 1, 3 and 4 are formed in the (active) semiconductor layer 2 of the semiconductor structure 22. In this embodiment, the semiconductor layer 2 can also be referred to as the JFET region 2. The semiconductor layer 2 may be a lightly doped epitaxial semiconductor layer, e.g. an epitaxial silicon carbide layer grown on a silicon carbide substrate 24. The gate poly layer 5 is recessed in the silicon substrate 24 and contacts the doped regions 1, 2 and 3 laterally via an insulating gate oxide.

In FIG. 7A, the gate structure 23 has been provided comprising the gate oxide and the conductive gate layer 5 (e.g. poly) in a trench through the active silicon layer 2 and into the substrate 24. In particular, to provide the semiconductor structure 22 at the stage illustrated in FIG. 7A, the method may comprise the following preceding steps in the following order:
1. Forming a gate oxide layer (e.g. silicon oxide);
2. Depositing a gate poly layer 5 on the gate oxide layer;
3. Doping the gate poly layer 5;
4. Patterning the gate structure 23; and
5. Etching the gate poly layer 5.

In FIG. 7B, an interlay dielectric (ILD) layer 9 has been deposited on the wafer 20. The ILD layer 9 covers the source region 3 and the gate structure 23. In this embodiment, the ILD layer 9 may be used as a protective insulating layer on the gate poly 5, instead of depositing a dedicated TEOS layer 6 as in FIG. 5A. The ILD 9 may comprise silicon oxide or a combination of silicon oxide and a reflowable BPTEOS.

In FIG. 7C, the ILD 9 is patterned and etched to form openings 111 down to the active silicon layer 2. The etch stops on the silicon.

In FIG. 7D, a trench 108 is etched into the (active) semiconductor layer 2. The etch removes a part of the N+ regions 3 and a part of the P+ region 4 and exposes sidewalls of the N+ regions 3.

In certain embodiments, forming the trench 108 may advantageously use a new etching technique. Due to the inert nature of SiC, dry etching of SiC can be challenging. Existing masks and etch parameters for etching silicon are in general not applicable to SiC. The new etching technique comprises a plasma etch that provides 1) a high SiC-to-SiO2 etch selectivity (causing minimal oxide loss), 2) sloped contact trench sidewalls (causing an enlarged sidewall contact area), and 3) a smooth trench surface, which can reduce contact resistivity. The plasma etch may be based on sulphur hexafluoride (SF6) gas chemistry. The plasma etch may further comprise an optimal combination of chamber pressure and RF power.

In FIG. 7E, the ohmic contact 8 is formed in the trench 108. The ohmic contact is formed on the N+ region 3 (i.e. in direct contact with the source region) and on the P+ region 4 (providing a short between the two regions). The ohmic contact 8 may be formed by depositing Ni, thermally reacting the Ni with the underlying SiC material to form a silicide, and then removing any excess (unreacted) Ni. Alternatively, the ohmic contact may be formed by titanium.

In FIG. 7F, a metal via 10 (also referred to as a “plug”) is formed in the opening 111 of the ILD 9 to contact the ohmic contacts 8. Forming the metal vias 10 may comprise depositing one or more barrier layers 14, depositing tungsten and then removing the tungsten on top of the ILD 9 by etching. The etchback to remove the excess tungsten typically stops on the barrier layers.

In FIG. 7G, a power metal layer 13 is deposited over the wafer 20. The power metal layer 13 may comprise copper. The metal plug 10 provides an electrical contact between the power metal layer and the N+ region 3 (i.e. the source region) of the transistor. Due to the metal plug 10, the power metal 13 does not have to reach down into trench 108 or trench 111, which can prevent metal filling void and allow for a smaller footprint of the source contact. The power metal layer 13 is arranged substantially flat on top of the metal plug 10.

In general, embodiments described herein provide a silicon carbide device (e.g. a vertical transistor) comprising:
a trench contact structure configured to connect to a part of a transistor (e.g. the source, drain or gate), wherein the trench contact structure comprises:
a trench comprising sidewalls;
a silicide layer located in the trench and covering the sidewalls; and
a metal contact element (e.g. a tungsten plug) located in the trench and connected to the part of the transistor via the silicide layer.

The part of the transistor is typically the source (or source region) of the transistor but may also be the drain (or drain region) in some embodiments.

Typically, the contact structure comprises the source contact of a vertical MOSFET and in particular a power MOSFET as described herein. The transistor may be a so called trench MOSFET with the gate recessed in the silicon (instead of being formed on top of the silicon surface).

The device may further comprise:
a semiconductor layer comprising a contact region (e.g. a source region of a source of the transistor), wherein the trench is located in the semiconductor layer so that the sidewalls interface the contact region; and
a power metal layer directly connected to the metal contact element.

The semiconductor layer typically comprises an epitaxial structure comprising one or more epitaxially grown semiconductor layers on. The semiconductor layer comprises a so called active region or active layer within which the contact region is formed.

Typically, the structure comprises a dielectric layer (e.g. silicon oxide) located between the semiconductor layer and the power metal layer. The dielectric layer may be an interlayer dielectric (ILD) layer. The contact structure may further comprise a gate structure comprising a patterned gate poly layer located on or recessed in the semiconductor layer and at least partly isolated from the metal contact element and from the power metal layer by the dielectric layer. The metal contact element may then extend through the dielectric layer between the power metal layer and the semiconductor layer. A top (surface) of the metal contact element may be substantially level with the dielectric layer. This can provide an improved flat surface on which to deposit the power metal layer.

The metal contact element may have any suitable shape, but advantageously has a small cross section to allow for a smaller footprint. For example, the metal contact element may comprise a cylindrical shape (circular cross section) or a cuboid shape (rectangular cross section). The trench can in one case have a width that is less than or equal to 1.0 μm.

The power metal layer is generally a different metal than the metal of the metal contact element and is provided in a separate deposition step after filling the trench with metal. The power metal layer typically comprises copper or aluminium, whereas the metal contact element may in one case comprise tungsten.

The power metal layer can be arranged substantially planar at least over the contact region of the semiconductor layer. This can provide improved topography.

The contact region comprises one or more doped regions. For example the contact region may comprise an N-doped region (e.g. N+) and a P-doped region (e.g. P+) in a P-doped well (P-Well). The sidewalls of the trench may then comprise an interface to the N-doped region, and a bottom of the trench may comprise an interface to the P-doped region.

The N-doped region has a doping concentration in the range of 1.0E19-1.0E21 cm⁻³, the P-doped region as a doping in the range of 1.0E19-1.0E21 cm⁻³, and the P-doped well (or N-doped well for p-channel MOSFET) has a doping concentration in the range of 1.0E17-1.0E18 cm⁻³.

While embodiments described above focus on n-channel MOSFETs, the described contact structure can also be used in a p-channel MOSFET.

Embodiments described herein also provide a method of forming a contact structure for connecting to a part of a transistor of a silicon carbide device (such as the silicon carbide device described above). The part of the transistor can be the source, drain, or gate of the transistor. The method comprises the following steps:
forming a trench comprising sidewalls;
forming a silicide layer (e.g. in an RTP) located in the trench and covering the sidewalls; and
filling the trench with metal (e.g. tungsten) to form a metal contact element connected to the part of the transistor via the silicide layer.

The method may further comprise:
providing a semiconductor layer and doping the semiconductor layer to form a contact region, wherein the trench is formed in the semiconductor layer so that the sidewalls interface the contact region; and
providing a power metal layer directly connected to the metal contact element.

The method may further comprise providing a dielectric layer on the semiconductor layer before forming the trench, wherein the trench extends through the dielectric layer and into the semiconductor layer.

The metal contact element can be formed so that it is substantially level with the dielectric layer.

The method may further comprise forming a gate structure comprising patterning a gate poly layer located on or recessed in the semiconductor layer.

The power metal layer may comprise copper or aluminium. For example, the power metal layer may be formed using a copper seed layer or by aluminium sputtering for example. The power metal layer can be substantially planar at least over the contact region of the semiconductor layer.

The step of doping may comprise forming an N-doped region and a P-doped region in a P-doped well, and wherein the trench is formed so that the sidewalls comprise an interface to the N-doped region. The trench can be formed so that a bottom of the trench comprises an interface to the P-doped region.

While specific embodiments of the invention have been described above, it will be appreciated that the invention may be practiced otherwise than as described. The descriptions above are intended to be illustrative, not limiting. It will be apparent to one skilled in the art that modifications may be made to the invention as described without departing from the scope of the claims set out below.

Each feature disclosed or illustrated in the present specification may be incorporated in the invention, whether alone or in any appropriate combination with any other feature disclosed or illustrated herein.

What is claimed is:

1. A silicon carbide device comprising:
a trench contact structure configured to connect to a part of a transistor, wherein the trench contact structure comprises:
a trench comprising sidewalls;
a silicide layer located in the trench and covering the sidewalls; and
a metal contact element located in the trench and connected to the part of the transistor via the silicide layer.

2. A silicon carbide device according to claim 1, wherein the part of the transistor is a source or a drain.

3. A silicon carbide device according to claim 1, further comprising:
a semiconductor layer comprising a contact region, wherein the trench is located in the semiconductor layer so that the sidewalls interface the contact region;
a power metal layer directly connected to the metal contact element; and
a dielectric layer located between the semiconductor layer and the power metal layer.

4. A silicon carbide device according to claim 3, further comprising a gate structure comprising a patterned gate poly layer located on or recessed in the semiconductor layer and at least partly isolated from the metal contact element and from the power metal layer by the dielectric layer.

5. A silicon carbide device according to claim 3, wherein the metal contact element extends through the dielectric layer between the power metal layer and the semiconductor layer.

6. A silicon carbide device according to claim 3, wherein a top of the metal contact element is substantially level with the dielectric layer.

7. A silicon carbide device according to claim 3, wherein the power metal layer comprises copper or aluminium.

8. A silicon carbide device according to claim 3, wherein the power metal layer is arranged substantially planar at least over the contact region of the semiconductor layer.

9. A silicon carbide device according to claim 3, wherein the contact region comprises an N-doped region and a P-doped region in a P-doped well, and wherein the sidewalls comprise an interface to the N-doped region.

10. A silicon carbide device according to claim 9, wherein a bottom of the trench comprises an interface to the P-doped region.

11. A silicon carbide device according to claim 9, wherein the N-doped region has a doping concentration in the range of 1.0E19-1.0E21 cm⁻³, the P-doped region has a doping in the range of 1.0E19-1.0E21 cm⁻³, and the P-doped well has a doping concentration in the range of 1.0E17-1.0E18 cm⁻³.

12. A silicon carbide device according to claim 1, wherein the metal contact element comprises a cylindrical shape or a cuboid shape.

13. A silicon carbide device according to claim 1, wherein the trench has a width that is less than or equal to 1 μm.

14. A method of forming a trench contact structure connected to a part of a transistor of a silicon carbide device, the method comprising the following steps:
forming a trench comprising sidewalls;
forming a silicide layer located in the trench and covering the sidewalls; and
filling the trench with metal to form a metal contact element connected to the part of the transistor via the silicide layer.

15. A method according to claim 14, wherein the part of the transistor is a source or a drain.

16. A method according to claim 14, further comprising:
providing a semiconductor layer and doping the semiconductor layer to form a contact region, wherein the trench is formed in the semiconductor layer so that the sidewalls interface the contact region; and
providing a power metal layer directly connected to the metal contact element.

17. A method according to claim 16, further comprising providing a dielectric layer on the semiconductor layer before forming the trench, wherein the trench extends through the dielectric layer and into the semiconductor layer.

18. A method according to claim 17, wherein the metal contact element is formed so that it is substantially level with the dielectric layer.

19. A method according to claim 16, further comprising forming a gate structure comprising patterning a gate poly layer located on or recessed in the semiconductor layer.

20. A method according to claim 16, wherein the power metal layer comprises copper or aluminium.

21. A method according to claim 16, wherein the power metal layer is substantially planar at least over the contact region of the semiconductor layer.

22. A method according to claim 16, wherein the step of doping comprises forming an N-doped region and a P-doped region in a P-doped well, and wherein the trench is formed so that the sidewalls comprise an interface to the N-doped region.

23. A method according to claim 22, wherein the trench is formed so that a bottom of the trench comprises an interface to the P-doped region.
